(19) United States
(12) Patent Application Publication
(10) Pub. No.: US 2007/0002913 A1
(43) Pub. Date: Jan. 4, 2007

(54) Structure of laser

(75) Inventors: Wei Chang, Taipei City (TW); Tsung-Wei Lin, Luodong Town (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/171,342

(22) Filed: Jul. 1, 2005

(51) Int. Cl. H01S 5/00; H01S 3/04; H01S 3/00

(52) U.S. Cl. 372/43.01; 372/109

(57) ABSTRACT

A structure of laser is disclosed. The laser structure comprises: a plurality of pins, one of which having a large area connection part on the top, wherein the connection part has two outwardly extending plates on both sides; a photo diode and a laser diode mounted on the connection part for being connected to the other pins by conducting wires; and a housing covered the top of the pins, wherein the outwardly extending plates are extended outside of the housing to form two conducting terminals on the upper end of the laser structure such that the user is provided with convenience and enabled to make more applicable variations.

### FIELD OF THE INVENTION

The present invention relates to a structure of laser or the like for providing the conducing terminals in different directions and increasing the heat-sinking area and the heat-sinking efficiency.

### BACKGROUND OF THE INVENTION

The photoelectric industry relates to a field that couples the electronics with the optics, wherein the light source for use in the fiber communication is mainly a light emitting diode or a laser diode.

As shown in FIG. 5, the conventional laser structure comprises: a base 110, a diode bracket 120, and a diode 130. Two pins 111 are mounted on the backside of the base 110 for being connected to the power source. When the pins 111 are electrified, the light beams 131 are emitted from the front and backside of diode 130.

In order to protect the diode of the general laser structure, the base on which the diode is mounted is covered with a housing on which a center hole is formed. Accordingly, the pins are located on the same side of the common laser structure to enable the laser structure to be coupled to a printed circuit board by which the power source is supplied. When the laser structure is used independently and not coupled to the printed circuit board, the light emitting direction of the light beams has high priority. In order to be adapted to the direction of the pins, the conducting wires are used to connect the power source and the pins of the laser structure. Accordingly, the major drawback of the conventional laser structure consists in the chaotic wiring.

In view of the drawback of the conventional structure, a laser structure with less orientation limitation is provided in accordance with the motive of the present invention.

### SUMMARY OF THE INVENTION

It is a main object of the present invention to provide an improved structure for the laser. When assembled to the power source, the laser structure is prevented from limitation of direction by addition of the conducting terminals in different directions.

It is another object of the present invention to provide a structure of laser for increasing the heat-sinking area and the heat-sinking efficiency.

In order to achieve the aforementioned object, a laser structure is disclosed. The laser structure comprises: a plurality of pins, one of which having a large area connection part on the top, wherein the connection part has two outwardly extending plates on both sides; a photo diode and a laser diode mounted on the connection part for being connected to the other pins by conducting wires; and a housing covered the top of the pins, wherein the outwardly extending plates are extended outside of the housing to form-two conducting terminals on the upper end of the laser structure.

The aforementioned aspects and advantages of the present invention will be readily clarified in the description of the preferred embodiments and the enclosed drawings of the present invention.

### BRIEF DESCRIPTION OF THE DRAWINGS

FIG. 1 is an elevational view showing the laser structure of the present invention.

FIG. 2 is an exploded view showing the laser structure of the present invention.

FIG. 3 is a cross-sectional view showing the laser structure of the present invention.

FIG. 4 is a schematic view showing the usage of the laser structure of the present invention.

FIG. 5 is a cross-sectional view showing the conventional laser structure.

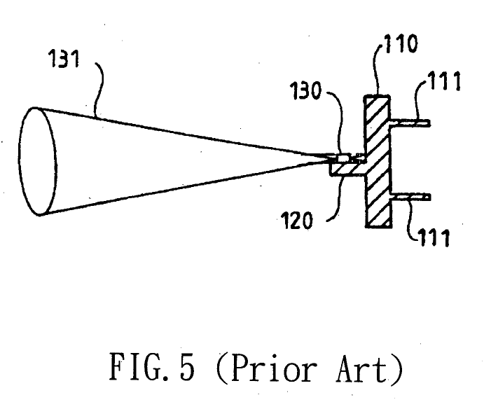

### DETAILED DESCRIPTION OF THE PREFERRED EMBODIMENT

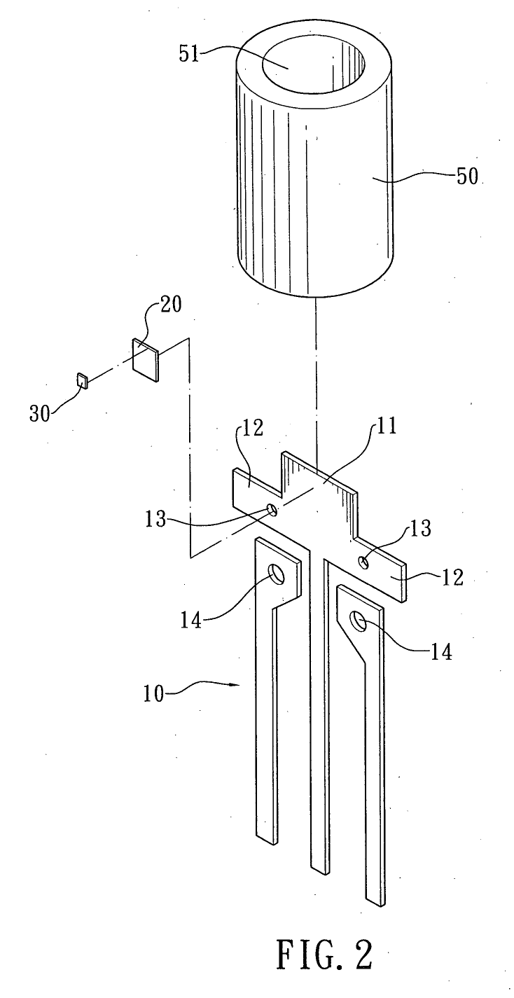

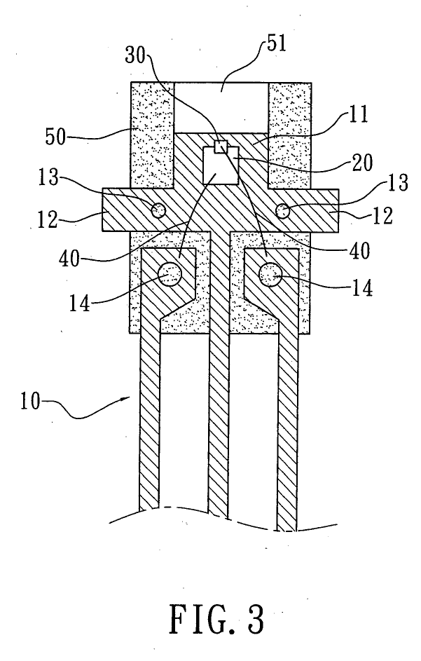

Referring to FIG. 2 and FIG. 3, a laser structure of the present invention comprises: several pins 10, a photo diode 20, a laser diode 30, two conducting wires 40, and a housing 50, wherein one of these pins 10 comprises a large area connection part 11 on which two outwardly extending plates 12 are formed on both sides. Besides, a through hole 13 is formed on the outwardly extending plates 11, and a through hole 14 is formed on the other pins 10.

The photo diode 20 is coupled with the connection part 11. The laser diode 30 is partially stacked on the photo diode 20. Besides, the photo diode 20 and the laser diode 30 are electrically connected to the other pins 10 by two conducting wires 40.

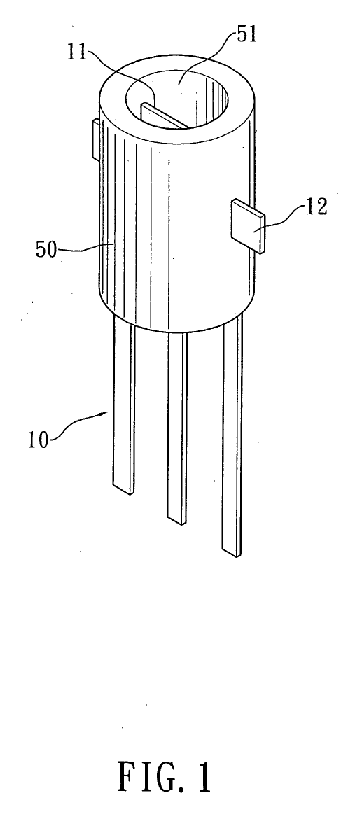

Thereafter, the housing 50 having a center tunnel 51 is formed by injection molding method for covering the top of the pins 10. The compactness degree between the housing 50 and the pins 10 is increased by the through holes 14 on the pins 10 and the through holes 13 on the outwardly extending plates 12. Besides, the connection part 11 is located in the center tunnel 51 of the housing 50 such that the housing 50 is prevented from covering the laser diode 30. When assembled, as shown in FIG. 1, the outwardly extending plates 12 are extended outside of the housing 50 such that the laser structure is provided with conducting terminals on the upper and lower ends.

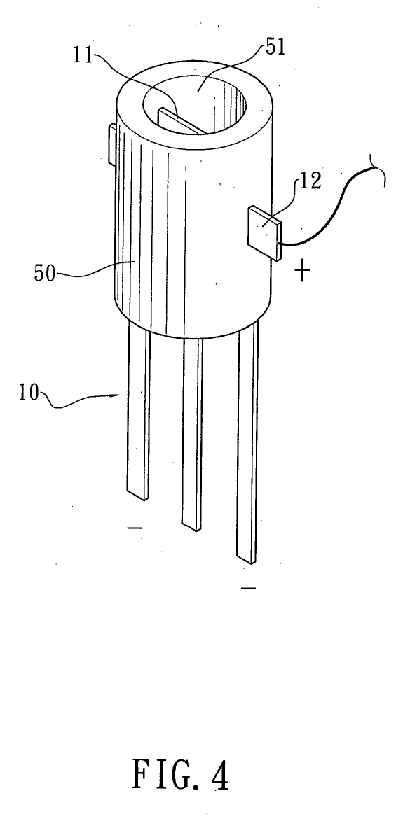

Accordingly, when the present invention is put into practice, the positive and negative poles of the power source are connected to the pins 10, which are exposed on the bottom of the housing 50. Alternatively, in order to provide more choices for the user, the positive pole of the power source may be connected to the outwardly extending plate 12, as shown in FIG. 4. Furthermore, the outwardly extending plates 12 are designed to enlarge the surface area of the connection part 11 for further increasing the heat-sinking area and the heat-sinking efficiency.

From the above-mentioned description, it is apparent that the laser structure of the present invention has the following advantages in which:

1. The connection part is provided with two outwardly extending plates. Accordingly, when the connection part is assembled with the housing, the outwardly extending plates are extended outside of the housing to provide the laser structure with the conducting terminals on the upper end.

2. The surface area of the connection part is enlarged by the outwardly extending plates to increase the heat-sinking area and the heat-sinking efficiency.

3. The conducting terminals are located on the upper and lower ends of the laser structure. Accordingly, the user is provided with convenience and enabled to make more applicable variations.

On the basis of the aforementioned description, the laser structure of the present invention satisfies all requirements for a patent and is submitted for a patent.

While the preferred embodiment of the invention has been set forth for the purpose of disclosure; modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. A laser structure, comprising:
a plurality of pins, one of which having a large area connection part on the top, wherein the connection part has two outwardly extending plates on both sides;
a photo diode and a laser diode, mounted on the connection part for being connected to the other pins by two conducting wires; and
a housing, covered the top of the pins, wherein the outwardly extending plates are extended outside of the housing to form two conducting terminals on the upper end of the laser structure.

2. The laser structure of the claim 1, wherein a through hole is formed on the other pins.

3. The laser structure of the claim 1, wherein a through hole is formed on the outwardly extending plates.

4. The laser structure of the claim 1, wherein a center hole is formed on the housing.

5. The laser structure of the claim 1, wherein the laser diode is partially stacked on the photo diode.

6. The laser structure of the claim 1, wherein the housing is an injection molding housing.
